(19) United States
(12) Patent Application Publication
(10) Pub. No.: US 2026/0367155 A1
(43) Pub. Date: Nov. 19, 2026

(54) BATTERY DIAGNOSING APPARATUS AND A BATTERY DIAGNOSING SYSTEM INCLUDING THE SAME

(71) Applicants: HYUNDAI MOTOR COMPANY, Seoul (KR); KIA CORPORATION, Seoul (KR)

(72) Inventors: Hyun Jun Jang, Hwaseong-si (KR); Tae Kyu Kang, Hwaseong-si (KR); Hyun Jun Jo, Hwaseong-si (KR); Min Jun Park, Hwaseong-si (KR); Woo Sung Kim, Hwaseong-si (KR); Si Joong Kim, Hwaseong-si (KR)

(73) Assignees: HYUNDAI MOTOR COMPANY, Seoul (KR); KIA CORPORATION, Seoul (KR)

(21) Appl. No.: 19/354,584

(22) Filed: Oct. 9, 2025

(30) Foreign Application Priority Data
May 19, 2025 (KR) 10-2025-0064792

(51) Int. Cl. G01R 31/367; G01R 31/3842; G01R 31/392; G01R 31/396; G06T 7/90; G06T 11/10; G06T 11/26; H01M 10/42; H01M 10/48

(52) U.S. Cl. CPC G01R 31/367; G01R 31/3842; G01R 31/396; G06T 7/90; G06T 11/10; G06T 11/26; H01M 10/425; H01M 10/4285; H01M 10/482; G01R 31/392; G06T 2207/10024; H01M 2010/4271; H01M 2010/4278

(57) ABSTRACT

A battery diagnosis apparatus includes a memory configured to store least one instruction. The battery diagnosis apparatus also includes a processor configured to execute the at least one instruction to receive charge-discharge signals corresponding to each of a plurality of cells of a battery having the plurality of cells, transform the charge-discharge signals, and output pixel data maps on a cell-by-cell basis.

### CROSS-REFERENCE TO THE RELATED APPLICATION

This application claims the benefit of and priority to Korean Patent Application No. 10-2025-0064792, filed May 19, 2025, the entire contents of which are hereby incorporated herein by reference.

### BACKGROUND

### 1. Technical Field

The present disclosure relates to an apparatus configured to diagnose batteries and a battery diagnosis system including the same.

### 2. Description of the Related Art

A battery is a device capable of converting chemical energy into electrical energy for storage and supply. Recently, batteries have been utilized as core power sources in various fields such as electric vehicles, energy storage systems (ESS), and portable electronic devices. In particular, lithium-ion batteries are widely used based on their advantages of high energy density, long lifespan, and light weight.

Such batteries may experience gradual performance degradation due to internal chemical reactions during charge-discharge processes, and degradation may be accelerated by various operating conditions such as overcharging, over-discharging, and high-temperature environments. Accordingly, various methods to diagnose battery conditions and detect abnormalities may be used.

Some battery diagnosis methods have limitations in providing quantitative analysis of battery conditions beyond simple normal or abnormal determinations.

The matters described in this Background section are merely for enhancement of understanding of the general background of the present disclosure and should not be taken as an acknowledgement or any form of suggestion that the matters form the related art already known to a person having ordinary skill in the art.

### SUMMARY

Aspects of the present disclosure provide a technology that can accurately diagnose battery conditions and detect abnormalities at an early stage, thereby securing stability and reliability of batteries.

Aspects of the present disclosure provide a technology that can diagnose battery conditions quantitatively and analyze fault types and severity levels through comprehensive analysis of battery system data.

Aspects of the present disclosure provide a battery diagnosis apparatus and method configured to enable quantitative diagnosis of battery conditions while preventing limitations of conventional simple normal or abnormal determinations.

According to an embodiment of the present disclosure, a battery diagnosis apparatus is provided. The battery diagnosis apparatus includes a memory configured to store at least one instruction, and a processor configured to execute the at least one instruction to receive charge-discharge signals corresponding to each of a plurality of cells of a battery having the plurality of cells, transform the charge-discharge signals, and output pixel data maps on a cell-by-cell basis.

The pixel data maps may include a plurality of pixel data representing relative values of charge-discharge signals of respective cells with respect to charge-discharge signals of the plurality of cells. The processor may be configured to transform the charge-discharge signals into primary transform signals including one or more domains of time and frequency, and output the pixel data maps based on the primary transform signals through normalization processes.

According to another embodiment of the present disclosure, a battery diagnosis system is provided. The battery diagnosis system includes a battery including a plurality of cells, a battery management apparatus configured to monitor the battery, and a battery diagnosis apparatus configured to receive charge-discharge signals corresponding to each of the plurality of cells from the battery management apparatus and transform the charge-discharge signals to output pixel data maps on a cell-by-cell basis.

According to various embodiments of the present disclosure, it becomes possible to diagnose battery conditions quantitatively as well as determine normal or abnormal status, thereby enabling analysis of fault types and severity levels of batteries. Additionally, according to embodiments of the present disclosure, it becomes possible to provide battery conditions as visual images, thereby enabling intuitive recognition of battery status. Furthermore, according to embodiments of the present disclosure, diagnosis is performed at the level of an entire battery system including a plurality of cells rather than individual cells, thereby enabling reflection of more information in diagnosis compared to individual cell-level diagnosis. Moreover, according to embodiments of the present disclosure, implementation may be advantageous in terms of application since it can be achieved through application of software logic alone without requiring additional hardware for battery diagnosis.

The effects obtainable from the present disclosure are not limited to the effects mentioned above. Other effects not mentioned herein should be more clearly understood by those having ordinary skill in the art from the following description.

### BRIEF DESCRIPTION OF THE DRAWINGS

The above and other objects, features, and other advantages of the present disclosure should be more clearly understood from the following detailed description taken in conjunction with the accompanying drawings, in which:

FIG. 1 shows a configuration of a battery diagnosis system according to an embodiment of the present disclosure;

FIG. 2 illustrates an example of charge-discharge signals according to an embodiment of the present disclosure;

FIG. 3 depicts an example of correction signals according to an embodiment of the present disclosure;

FIG. 4 is a view for explaining extraction of effective range signals according to an embodiment of the present disclosure;

FIG. 5 presents an image of primary transform signals according to an embodiment of the present disclosure;

FIG. 6 explains an image of pixel data maps on a cell-by-cell basis according to an embodiment of the present disclosure;

FIG. 7 illustrates an image of pixel data maps on a cell-by-cell basis according to an embodiment of the present disclosure;

FIG. 8 shows an image of pixel data maps on a cell-by-cell basis according to an embodiment of the present disclosure; and

FIG. 9 depicts an output form of pixel data maps for an entire battery according to an embodiment of the present disclosure.

### DETAILED DESCRIPTION

Hereinafter, embodiments of the present disclosure are described in detail with reference to the accompanying drawings. In the drawings, the same or similar elements are designated by the same reference numerals regardless of the numerals in the drawings, and redundant description thereof have been omitted.

Specific structural or functional descriptions of embodiments of the present disclosure are provided only for the purpose of describing embodiments according to the present disclosure, and embodiments according to the present disclosure may be implemented in various forms and should not be construed as being limited to the embodiments described in the present disclosure.

Embodiments of the present disclosure are described below in detail with reference to the accompanying drawings in which embodiments of the present disclosure are illustrated. However, this is not intended to limit embodiments according to the concept of the present disclosure to particular disclosed forms. Rather, the present disclosure should be understood to include all modifications, equivalents, and substitutes included in the spirit and technical scope of the present disclosure.

Unless defined otherwise, all terms used herein, including technical or scientific terms, have the same meaning as commonly understood by one having ordinary skill in the art to which the present disclosure pertains. Terms such as those defined in commonly used dictionaries should be interpreted as having meanings consistent with those in the context of related art, and should not be interpreted as having ideal or excessively formal meanings unless explicitly defined in the present disclosure.

In the following description of embodiments, the term “predetermined” means that numerical values of parameters are determined in advance when parameters are used in processes or algorithms. The numerical values of parameters may be set when processes or algorithms start or may be set during periods when processes or algorithms are performed, according to embodiments.

The suffixes “module” and “unit” for components used in the following description are given or used interchangeably considering only ease of specification writing, and do not have meanings or roles that are distinct from each other.

In describing embodiments of the present disclosure, detailed descriptions of related known technologies have been omitted where it was determined that the detailed descriptions may obscure the gist of the present disclosure. Additionally, the accompanying drawings are provided merely to enhance understanding of embodiments of the present disclosure. The technical spirit of the present disclosure is not limited by the accompanying drawings, and should be understood to include all modifications, equivalents, and substitutes included in the spirit and technical scope of the present disclosure.

Terms including ordinal numbers such as first and second may be used to describe various components, but the components are not limited by the terms. The terms are used only for the purpose of distinguishing one component from another component.

When a component is referred to as being “connected” or “coupled” to another component, it should be understood that the component may be directly connected or coupled to the other component, or one or more other components may exist in between. On the other hand, when a component is referred to as being “directly connected” or “directly coupled” to another component, it should be understood that no other components exist in between.

Singular expressions include plural expressions unless the context clearly indicates otherwise.

In the present disclosure, terms such as “comprise” or “have” are intended to designate that features, numbers, steps, operations, components, parts, or combinations thereof described in the present disclosure exist, and should be understood as not precluding the existence or addition of one or more other features, numbers, steps, operations, components, parts, or combinations thereof.

When a component, controller, device, element, unit, apparatus, or the like of the present disclosure is described as having a purpose or performing an operation, function, or the like, the component, controller, device, element, unit, apparatus, or the like should be considered herein as being “configured to” meet that purpose or to perform that operation or function. Each component, controller, device, element, unit, apparatus, and the like may separately embody or be included with a processor and a memory, such as a non-transitory computer readable media, as part of the apparatus.

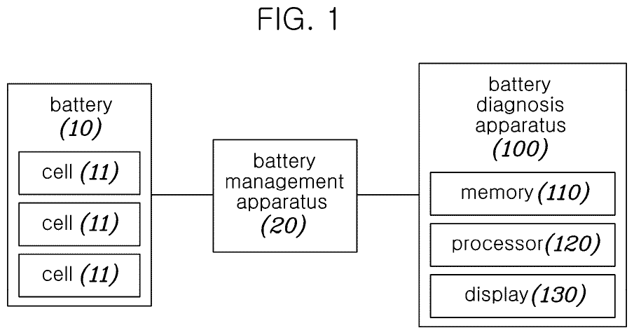

Referring to FIG. 1, a battery diagnosis system according to an embodiment may include a battery 10 including a plurality of cells 11, a battery management apparatus 20 configured to monitor conditions of the battery 10, and a battery diagnosis apparatus 100.

The battery diagnosis apparatus 100 includes a memory 110 and a processor 120. The battery diagnosis apparatus 100 may be configured to receive charge-discharge signals of the battery from the battery 10 or the battery management apparatus 20.

In an embodiment, the memory 110 is a storage device configured to store data or instructions for executing programs. The memory 110 may include volatile and/or non-volatile storage media. For example, the memory 110 may include RAM (Random Access Memory), ROM (Read Only Memory), flash memory, EEPROM (Electrically Erasable Programmable Read-Only Memory), hard disk drives, and/or solid state drives. The memory 110 may be implemented as a single configuration or may be implemented as a plurality of modules.

The processor 120 may be configured to perform various functions for battery diagnosis according to embodiments of the present disclosure by executing at least one instruction stored in the memory 110. The processor 120 may be capable of performing judgments, calculations, and decisions necessary for control, and may include, for example, a CPU (Central Processing Unit), a DSP (Digital Signal Processor), an MCU (Micro Controller Unit), and an AP (Application Processor). The processor 120 may be implemented as a single chip or may be implemented in the form of a plurality of chips or modules.

In an embodiment, the processor 120 may be configured to receive charge-discharge signals corresponding to each of the plurality of cells 11 of the battery 10, and to transform the charge-discharge signals to output pixel data maps on a cell-by-cell basis.

The charge-discharge signals may refer to time-based condition profiles during charging or discharging processes of the battery 10. The charge-discharge signals may include, for example, one or more of voltage over time and SOC (State of Charge) during charging or discharging processes of each of the plurality of cells 11.

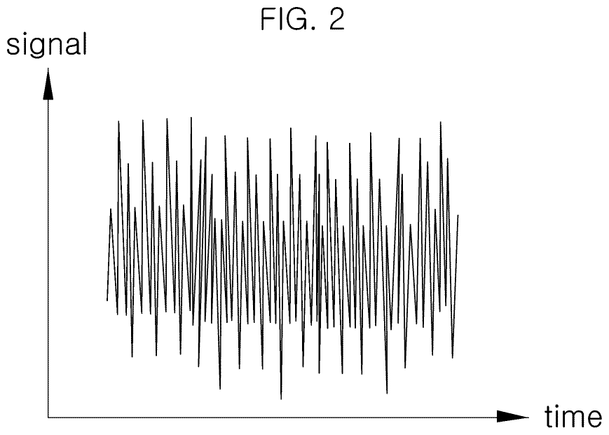

Referring to FIG. 2, charge-discharge signals input to the battery diagnosis apparatus 100 may be represented as graphs having time as a horizontal axis and signal values as a vertical axis as shown. For example, the signals in FIG. 2 may be voltage values of cells over time for some or all sections during charging or discharging processes.

In an embodiment, the processor 120 may be configured to output pixel data maps based on correction signals obtained by removing predetermined correction constants from the charge-discharge signals, rather than using the charge-discharge signals directly.

For example, the correction signals may be obtained by removing correction constants corresponding to average voltages of the plurality of cells 11 from voltage values over time. In this case, it becomes possible to analyze voltage-current of cells 11 showing different behavior from the average of the plurality of cells 11 through the correction signals.

As another example, the correction signals may be obtained by removing correction constants corresponding to predetermined open circuit voltages for each SOC of the plurality of cells 11 from voltage values over time. In this case, it becomes possible to analyze polarization voltage-current of the cells 11 through the correction signals.

As yet another example, the correction signals may be obtained by removing correction constants corresponding to predetermined reference capacities for each SOH (State of Health) of the plurality of cells 11 from SOC values over time. In this case, it becomes possible to analyze abnormal behavior of voltage-current due to factors other than effects by normal degradation through the correction signals.

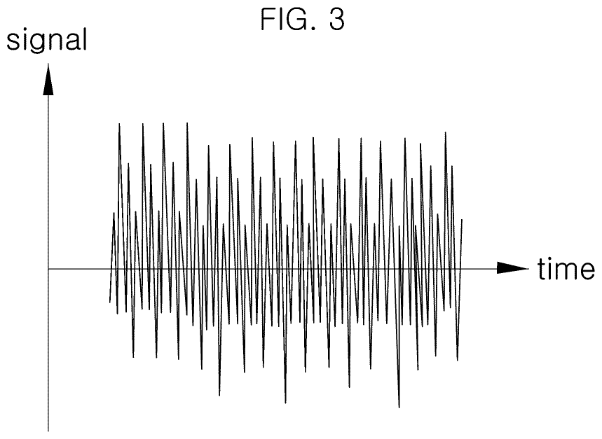

In various embodiments, the correction constants may be viewed as a kind of DC component. Referring to FIG. 3, for example, the correction signals may represent deviation components based on ‘0’ by removing the correction constants from the charge-discharge signals.

The pixel data maps may include a plurality of pixel data representing relative values of charge-discharge signals of each of the plurality of cells 11 with respect to charge-discharge signals of all of the plurality of cells 11. The pixel data maps may thus be represented as sets of pixel data, and each pixel data may have coordinates and values at corresponding coordinates.

In an embodiment, the processor 120 may be configured to transform the charge-discharge signals into primary transform signals including one or more domains of time and frequency, and to output the pixel data maps based on the primary transform signals.

For example, the processor 120 may be configured to transform the charge-discharge signals into primary transform signals having wavelet coefficient values in time and frequency domains through wavelet transform, and such domain transformation may be expressed by the following equations:

$$WT ( a , b ) = \int x ( t ) {Ψ}^{*} ( \frac{t - b}{a} ) dt$$

$$Ψ ( t ) = {π}^{- \frac{1}{4}} {e}^{{jw}_{0} t} {e}^{- \frac{{t}^{2}}{2}}$$

where WT(a,b) is a wavelet coefficient and a value of the primary transform signal, x(t) is the charge-discharge signal, Ψ(t) is a mother wavelet, Ψ* is a complex conjugate of the mother wavelet, a is a scale parameter inversely proportional to frequency, and b is a translation parameter corresponding to the time domain.

According to such domain transformation, it becomes possible to represent charge-discharge signals expressed in the time domain as primary transform signals in time and frequency domains, and the primary transform signals include information of frequency, time, and wavelet coefficients.

In addition, various techniques for transforming charge-discharge signals having time domains to frequency domains or to time and frequency domains, such as Fourier transform and short-time Fourier transform, may be applied to domain transformation in embodiments of the present disclosure.

The processor 120 may be configured to determine values of each of the plurality of pixel data by normalizing the primary transform signals as described above. For example, values of pixel data may be determined based on mean values of primary transform signals for the plurality of cells 11 and errors of primary transform signals of each of the plurality of cells 11.

In an embodiment, the processor 120 may be configured to determine values of pixel data using z-score normalization. Values of pixel data may be expressed by the following equation:

$${x}^{′} = \frac{x - u}{σ}$$

where x′ is a value of pixel data, x is a value of a primary transform signal corresponding to the pixel data, u is a mean of primary transform signals for the plurality of cells 11, and o is a standard deviation of primary transform signals for the plurality of cells 11.

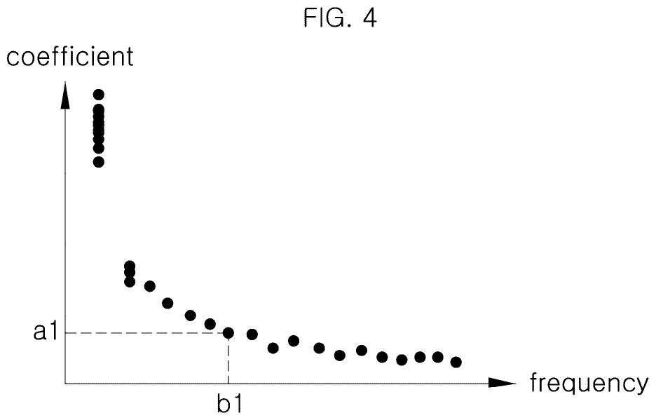

In an embodiment, the processor 120 may be configured to extract signals included in predetermined domain ranges from among the primary transform signals before determining values of pixel data through the primary transform signals. The predetermined domain ranges may include ranges in which values of the primary transform signals are equal to or greater than predetermined reference values. For example, referring to FIG. 4, the processor 120 may be configured to extract primary transform signals included in frequency sections (i.e., equal to or less than b1) in which values (coefficients) of the primary transform signals are equal to or greater than al, and output pixel data maps using only the extracted primary transform signals. When pixel data maps are output by extracting primary transform signals of effective ranges in this way, it becomes possible to maximize data that effectively acts for battery diagnosis in limited data ranges and images represented through them.

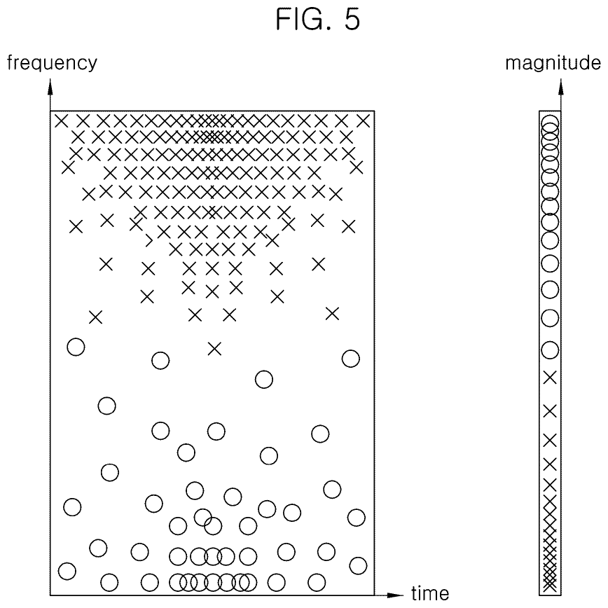

The processor 120 may be configured to output transform signal maps representing primary transform signals for each of the cells 11 before outputting pixel data maps on a cell-by-cell basis based on the primary transform signals. The transform signal maps may be represented as images as shown in FIG. 5. Referring to FIG. 5, in the images, horizontal axes represent time, vertical axes represent frequency, and colors at each point in the images may represent values of the primary transform signals. Although FIG. 5 illustrates scalograms for wavelet-transformed primary transform signals, images of transform signal maps may also be represented in other ways such as spectrograms or Fourier images.

In an embodiment, the processor 120 may be configured to transform and output the transform signal maps as pixel data maps. For example, the processor 120 may be configured to output pixel data maps by transforming pixel data included in the transform signal maps, i.e., values of the primary transform signals, into relative values with respect to pixel data of all of the plurality of cells 11. In this case, the relative values with respect to pixel data of all of the plurality of cells 11 may be, for example, values based on the z-score normalization described above.

In an embodiment, the transform signal maps may be understood as values obtained by analyzing charge-discharge signals of each cell 11 itself, and the pixel data maps may be understood as representing relative indicators of each cell 11 with respect to all of the plurality of cells 11.

The processor 120 may be configured to determine color values of pixel data based on relative values of charge-discharge signals of respective cells with respect to charge-discharge signals of all of the plurality of cells 11, and output pixel data maps with the determined color values. In an embodiment, the color values may correspond to different colors for individual values. The color values may include, for example, values between 0 (black) and 255 (white) or combinations of RGB values corresponding to red, green, and blue, respectively.

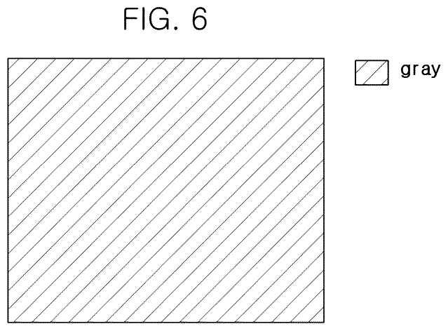

In an embodiment, referring to FIGS. 6-8, the processor 120 may be configured to determine color values of pixel data based on errors between values of pixel data obtained by normalizing primary transform signals and averages of all pixel data.

For example, when values of pixel data correspond to averages of all pixel data, the corresponding pixel data may have predetermined first color values. In an embodiment, the first color values may correspond to gray which is intermediate between white and black.

In this case, when values of pixel data are less than errors of averages of pixel data, color values of pixel data may be determined to progressively vary from the first color values to predetermined second color values according to magnitudes of errors with respect to averages of pixel data. On the other hand, when values of pixel data exceed errors of averages of pixel data, color values of pixel data may be determined to progressively vary from the first color values to predetermined third color values according to magnitudes of errors with respect to averages of pixel data.

For example, the second color values may correspond to black and the third color values may correspond to white, respectively, and accordingly, color values of each pixel data may correspond to colors between white and black according to errors with respect to averages of pixel data.

In an embodiment, the battery diagnosis apparatus 100 according to an embodiment may include a display 130 configured to visually output pixel data maps based on color values. The display 130 may be configured to output images representing pixel data maps according to color values under control of the processor 120 to provide diagnosis results of the battery 10 based on charge-discharge signals as intuitive visual images.

Such diagnosis results may be utilized not only for analyzing normal or abnormal status of the battery 10, but also for quantitatively analyzing conditions of the battery 10.

For example, referring to FIG. 6, an image of pixel data maps in which most areas are represented in gray is shown, and cells 11 corresponding to pixel data maps as in the example of FIG. 6 may be diagnosed as normal as having conditions corresponding to averages of the plurality of cells 11.

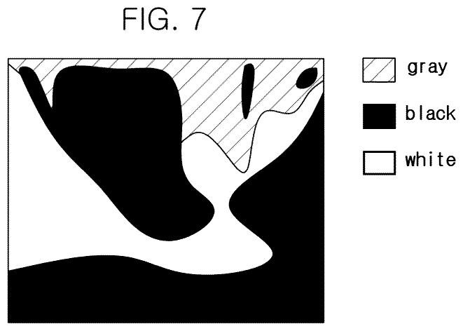

In contrast, referring to FIG. 7, an image of pixel data maps in which some portions are represented in black is shown. Cells 11 corresponding to pixel data maps as in the example of FIG. 7 may be diagnosed as abnormal as cells 11 having charge-discharge signals deviating from averages of the plurality of cells 11, and may represent micro short circuit types in which partial current leakage has occurred as cells 11 having relatively low charge-discharge signal values compared to averages of the plurality of cells 11. Additionally, severity of micro short circuits may be analyzed according to proportions occupied by gray in the pixel data maps.

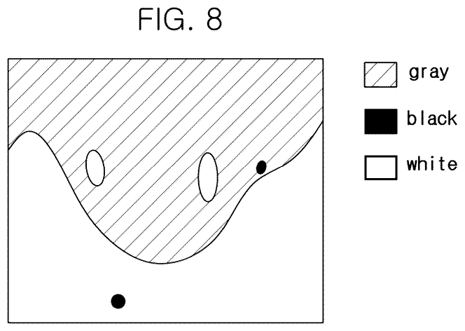

Additionally, referring to FIG. 8, an image of pixel data maps in which some portions are represented in white is shown. Cells 11 corresponding to pixel data maps as in the example of FIG. 8 may similarly be diagnosed as abnormal, and may represent lithium plating types in which lithium ions have precipitated in metal forms as cells 11 having relatively large charge-discharge signal values compared to averages of the plurality of cells 11. Additionally, severity of lithium plating may be analyzed according to proportions occupied by gray in the pixel data maps.

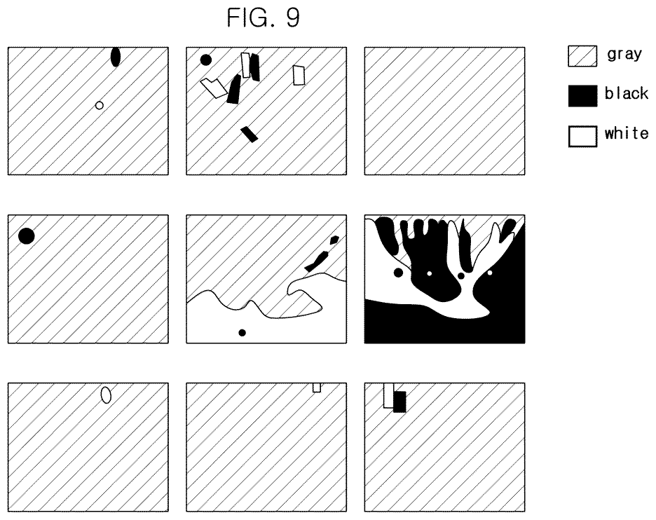

Referring to FIG. 9, pixel data maps of individual cell units may be combined into pixel data maps for the entire battery 10. In this case, it becomes possible to provide diagnosis results for the entire battery 10 at a glance.

According to such battery-level pixel data maps, it becomes possible not only to diagnose conditions of each cell 11 itself, but also to intuitively recognize which cells 11 in the entire battery 10 have abnormalities, and to visually recognize relative severity of abnormal conditions such as micro short circuits or lithium plating through differences in colors.

Although example embodiments of the present disclosure have been described for illustrative purposes, those having ordinary skill in the art should appreciate that various modifications, additions, and substitutions are possible, without departing from the scope and spirit of the present disclosure as claimed in the accompanying claims.

What is claimed is:

1. A battery diagnosis apparatus comprising:
a memory configured to store at least one instruction; and
a processor configured to execute the at least one instruction to:
receive charge-discharge signals corresponding to each of a plurality of cells of a battery, and
output a pixel data map on a cell-by-cell basis based on transforming the charge-discharge signals,
wherein the pixel data map includes a plurality of pixel data representing relative values of charge-discharge signals of respective cells with respect to charge-discharge signals of the plurality of cells.

2. The battery diagnosis apparatus of claim 1,
wherein the processor is configured to execute the at least one instruction to:
transform the charge-discharge signals into primary transform signals including one or both domains of time or frequency; and
output the pixel data map based on the primary transform signals.

3. The battery diagnosis apparatus of claim 2, wherein the processor is configured to execute the at least one instruction to transform the charge-discharge signals into the primary transform signals having wavelet coefficient values in time and frequency domains through wavelet transform.

4. The battery diagnosis apparatus of claim 2, wherein the processor is configured to execute the at least one instruction to determine values of each of the plurality of pixel data based on normalization of the primary transform signals for the plurality of cells.

5. The battery diagnosis apparatus of claim 4, wherein the processor is configured to execute the at least one instruction to determine values of each of the pixel data based on a mean value of the primary transform signals for the plurality of cells and errors of the primary transform signals of each of the plurality of cells.

6. The battery diagnosis apparatus of claim 2, wherein the processor is configured to execute the at least one instruction to:
extract signals included in a predetermined domain range among the primary transform signals; and
output the pixel data map based on the extracted primary transform signals.

7. The battery diagnosis apparatus of claim 6, wherein the predetermined domain range includes a range in which values of the primary transform signals are equal to or greater than a predetermined reference value.

8. The battery diagnosis apparatus of claim 2, wherein the processor is configured to execute the at least one instruction to output a transform signal map having the primary transform signals as pixel data on a cell-by-cell basis.

9. The battery diagnosis apparatus of claim 8, wherein the processor is configured to execute the at least one instruction to transform the pixel data included in the transform signal map into relative values with respect to pixel data of the plurality of cells and output the pixel data map.

10. The battery diagnosis apparatus of claim 1, wherein the processor is configured to execute the at least one instruction to output the pixel data map based on correction signals obtained by removing predetermined correction constants from the charge-discharge signals.

11. The battery diagnosis apparatus of claim 10, wherein the charge-discharge signals include one or both of voltage over time or State of Charge (SOC) during charging or discharging processes of each of the plurality of cells.

12. The battery diagnosis apparatus of claim 11, wherein the correction constants correspond to the voltage over time and include one or both of an average voltage of the plurality of cells or a predetermined open circuit voltage for each SOC of the plurality of cells.

13. The battery diagnosis apparatus of claim 11, wherein the correction constants correspond to the SOC over time and includes a predetermined reference SOC for each State of Health (SOH) of the plurality of cells.

14. The battery diagnosis apparatus of claim 1, wherein the processor is configured to execute the at least one instruction to:
determine a color value of the pixel data based on the relative values of charge-discharge signals of the respective cells with respect to charge-discharge signals of the plurality of cells; and
output the pixel data map based on the color values.

15. The battery diagnosis apparatus of claim 14, wherein the processor is configured to execute the at least one instruction to determine the color value of the pixel data based on an error between values of the pixel data and an average of the pixel data.

16. The battery diagnosis apparatus of claim 15, wherein the processor is configured to execute the at least one instruction to determine the color value of the pixel data as a predetermined first color value based on a value of the pixel data corresponding to the average of the pixel data.

17. The battery diagnosis apparatus of claim 16, wherein the processor is configured to execute the at least one instruction to determine the color value of the pixel data to progressively vary from the predetermined first color value based on the error between the value of the pixel data and the average of the pixel data.

18. The battery diagnosis apparatus of claim 16, wherein the processor is configured to execute the at least one instruction to:
determine the color value of the pixel data to progressively vary from the predetermined first color value to a predetermined second color value according to magnitude of the error, based on the value of the pixel data being less than the average of the pixel data; and
determine the color value of the pixel data to progressively vary from the predetermined first color value to a predetermined third color value according to magnitude of the error, based on the value of the pixel data exceeding the average of the pixel data.

19. The battery diagnosis apparatus of claim 14, further comprising a display configured to visually output the pixel data map based on the color value, wherein the processor is configured to execute the at least one instruction to control output of the display.

20. A battery diagnosis system comprising:
a battery including a plurality of cells;
a battery management apparatus configured to monitor the battery; and
a battery diagnosis apparatus configured to:
receive charge-discharge signals corresponding to each of the plurality of cells from the battery management apparatus, and
output a pixel data map on a cell-by-cell basis by transforming the charge-discharge signals,
wherein the pixel data map include a plurality of pixel data representing relative values of charge-discharge signals of the respective cells with respect to charge-discharge signals of the plurality of cells.
